(19) United States
(12) Patent Application Publication
(10) Pub. No.: US 2016/0010208 A1
(43) Pub. Date: Jan. 14, 2016

(54) DESIGN OF SUSCEPTOR IN CHEMICAL VAPOR DEPOSITION REACTOR

(71) Applicant: Applied Materials, Inc., Santa Clara, CA (US)

(72) Inventors: Yi-Chiau HUANG, Fremont, CA (US); Zuoming ZHU, Sunnyvale, CA (US)

(21) Appl. No.: 14/741,080

(22) Filed: Jun. 16, 2015

Related U.S. Application Data
(60) Provisional application No. 62/023,024, filed on Jul. 10, 2014.

(51) Int. Cl. C23C 16/458

(52) U.S. Cl. CPC C23C 16/458

(57) ABSTRACT

Embodiments described herein generally relate to an apparatus for depositing materials on a substrate. The apparatus includes a substrate support assembly. The substrate support assembly includes a susceptor and a substrate support ring disposed on the susceptor. The substrate support ring has a first surface for receiving the substrate and a second surface opposite the first surface. The second surface includes at least three protrusions and each protrusion has a tip that is in contact with the susceptor. The substrate support ring is comprised of a material having poor thermal conductivity, and the contact area between the substrate support ring and the susceptor is minimized, resulting in minimum unwanted heat conduction from the susceptor to the edge of the substrate.

### CROSS-REFERENCE TO RELATED APPLICATIONS

This application claims priority to U.S. Provisional Patent Application Ser. No. 62/023,024, filed on Jul. 10, 2014, which herein is incorporated by reference.

### FIELD

Embodiments described herein generally relate to semiconductor manufacturing, and more specifically, to an apparatus for depositing a material on a substrate.

### BACKGROUND

Integrated circuits are typically formed on substrates, particularly silicon wafers, by the sequential deposition of conductive, semiconducting or insulating layers. Continuous reduction in size of semiconductor devices is dependent upon more precise control of, for instance, the temperature of the substrate during the deposition process. Typically, the substrate is disposed on a heated susceptor during the deposition process. The substrate may be bowed because of a coating with a material having a very different coefficient of thermal expansion (CTE), or because of an inherent tensile stress. The bowed substrate, typically having a concave shape, is heated unevenly because a portion of the substrate is in contact with the heated susceptor while the remaining portion is not in contact with the heated susceptor.

Therefore, there is a need for a processing apparatus having improved substrate temperature uniformity.

### SUMMARY

Embodiments described herein generally relate to an apparatus for depositing materials on a substrate. The apparatus includes a susceptor and a substrate support ring disposed on the susceptor. The substrate support ring has a first surface for receiving the substrate and a second surface opposite the first surface. The second surface includes at least three protrusions and each protrusion has a tip that is in contact with the susceptor.

In one embodiment, an apparatus is disclosed. The apparatus includes a susceptor and a substrate support ring disposed on a surface of the susceptor. The substrate support ring includes a first surface for receiving a substrate and a second surface opposite the first surface. The second surface includes at least three protrusions, each protrusion has a tip, and each tip is in contact with the susceptor.

In another embodiment, an apparatus is disclosed. The apparatus includes a chamber body and a substrate support assembly disposed in the chamber body. The substrate support assembly includes a susceptor and a substrate support ring disposed on a surface of the susceptor. The substrate support ring includes a first surface for receiving a substrate, and a second surface opposite the first surface. The second surface includes at least three protrusions, each protrusion has a tip, and each tip is in contact with the susceptor.

In another embodiment, an apparatus is disclosed. The apparatus includes a susceptor having a surface, and at least three recesses are formed in the surface of the susceptor. The substrate support assembly further includes a substrate support ring disposed on the surface of the susceptor. The substrate support ring includes a first surface for receiving a substrate and a second surface opposite the first surface. The second surface includes at least three protrusions, each protrusion has a tip, and each tip is placed in a corresponding recess of the at least three recesses.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross sectional view of an apparatus for depositing materials on a substrate according to one embodiment described herein.

FIGS. 2A-2C illustrate a substrate support assembly according to embodiments described herein.

FIGS. 3A-3B illustrate a substrate support assembly according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to an apparatus for depositing materials on a substrate. The apparatus includes a substrate support assembly. The substrate support assembly includes a susceptor and a substrate support ring disposed on the susceptor. The substrate support ring has a first surface for receiving the substrate and a second surface opposite the first surface. The second surface includes at least three protrusions and each protrusion has a tip that is in contact with the susceptor.

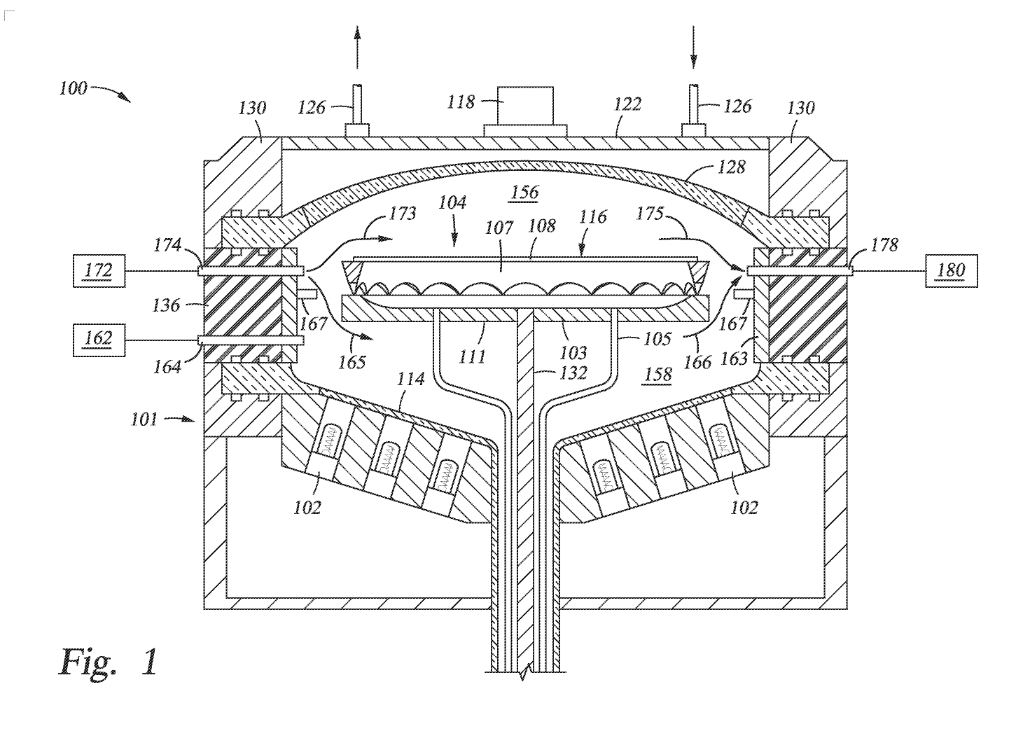

FIG. 1 is a cross sectional view of an apparatus 100 for depositing materials on a substrate 108 according to one embodiment. The apparatus 100 may be a thermal CVD chamber with an array of heating lamps 102 disposed below the substrate 108, as shown in FIG. 1. However, the apparatus 100 is not limited to the configuration shown in FIG. 1. In some embodiments, the substrate 108 may be heated by heating elements embedded in a susceptor supporting the substrate, and processing gases may be introduced through a showerhead disposed above the substrate 108. In some embodiments, the array of radiant heating lamps may be disposed over the substrate 108.

As shown in FIG. 1, the apparatus 100 includes a chamber body 101, an upper dome 128 and a lower dome 114 disposed in the chamber body 101, and a base ring 136 disposed between the upper dome 128 and the lower dome 114. In general, the upper dome 128 and the lower dome 114 are formed from an optically transparent material such as quartz. A substrate support assembly 104 is disposed in the chamber body 101 between the upper dome 128 and the lower dome 114. The substrate 108 (not to scale) can be brought into the apparatus 100 and positioned onto the substrate support assembly 104 through a loading port (not shown). The substrate support assembly 104 includes a susceptor 103 and a substrate support ring 107 disposed on the susceptor 103. The substrate support assembly 104 may be supported by a shaft 132. The substrate 108 may be disposed on the substrate support ring 107.

The substrate support assembly 104 is shown in an elevated processing position, but may be vertically traversed by an actuator (not shown) to a loading position below the processing position to allow lift pins 105 to contact the lower dome 114, passing through holes in the susceptor 103, and raise the substrate 108 from the substrate support ring 107. In some embodiments, the lift pins 105 do not contact the lower dome 114. Instead, the lift pins 105 may contact a support (not shown) disposed over the lower dome 114. A robot (not shown) may then enter the apparatus 100 to engage and remove the substrate 108 therefrom through the loading port.

The substrate support assembly 104, while located in the processing position, divides the internal volume of the chamber body 101 into a processing region 156 that is above the substrate 108, and a purging region 158 below the susceptor 103. The susceptor 103 and the substrate support ring 107 may be rotated during operation by the shaft 132 to minimize the effect of thermal and processing gas flow spatial anomalies within the chamber body 101 and thus facilitate uniform processing of the substrate 108. The substrate support assembly 104 is described in detail below.

One or more heating lamps, such as the array of heating lamps 102, may be disposed adjacent to and beneath the lower dome 114 in a specified manner around the central shaft 132 to independently control the temperature at various regions of the substrate 108 as the process gas passes over the substrate 108, thereby facilitating the deposition of a material onto the upper surface of the substrate 108.

An annular shield 167 may be optionally disposed around the substrate support assembly 104. The annular shield 167 may be coupled to a liner assembly 163 that is coupled to the base ring 136. The shield 167 prevents or minimizes leakage of heat/light noise from the lamps 102 to an upper surface 116 of the substrate 108 while providing a pre-heat zone for the process gases. The shield 167 may be made from SiC, sintered graphite coated with SiC, grown SiC, opaque quartz, coated quartz, or any similar, suitable material that is resistant to chemical breakdown by process and purging gases. In some embodiments, the annular shield 167 may be a preheat ring that is utilized to heat the process gases flowing from a process gas inlet 174 before the process gases reach the substrate 108.

A reflector 122 may be optionally placed over the upper dome 128 to reflect infrared light that is radiating off the substrate 108 back onto the substrate 108. The reflector 122 may be secured to the upper dome 128 using a clamp ring 130. The reflector 122 can be made of a metal such as aluminum or stainless steel. The efficiency of the reflection can be improved by coating a reflector area with a highly reflective coating such as with gold. The reflector 122 can have one or more machined channels 126 connected to a cooling source (not shown). An optical pyrometer 118 may be disposed on the reflector 122 for temperature measurement/control.

Process gases supplied from a process gas supply source 172 may be introduced into the processing region 156 through the process gas inlet 174 formed in the base ring 136. The process gas inlet 174 directs the process gases in a generally radially inward direction. During the film formation process, the substrate support assembly 104 may be in the processing position, which is adjacent to and at about the same elevation as the process gas inlet 174, allowing the process gases to flow along a flow path 173 across the upper surface 116 of the substrate 108 in a laminar flow fashion. The process gases exit the processing region 156 (along a flow path 175) through a gas outlet 178 located on the side of the apparatus 100 opposite the process gas inlet 174. Removal of the process gases through the gas outlet 178 may be facilitated by a vacuum pump 180 coupled thereto.

A purge gas may be supplied from a purge gas source 162 to the purging region 158 through an optional purge gas inlet 164 (or through the process gas inlet 174) formed in the base ring 136. The purge gas inlet 164 is disposed below the process gas inlet 174. The purge gas inlet 164 directs the purge gas in a generally radially inward direction. During the film formation process, the substrate support assembly 104 may be located at a position such that the purge gas flows along flow path 165 across a back side 111 of the susceptor 103 in a laminar flow fashion. The purge gas exits the purging region 158 (along flow path 166) and is exhausted out of the process chamber through the gas outlet 178.

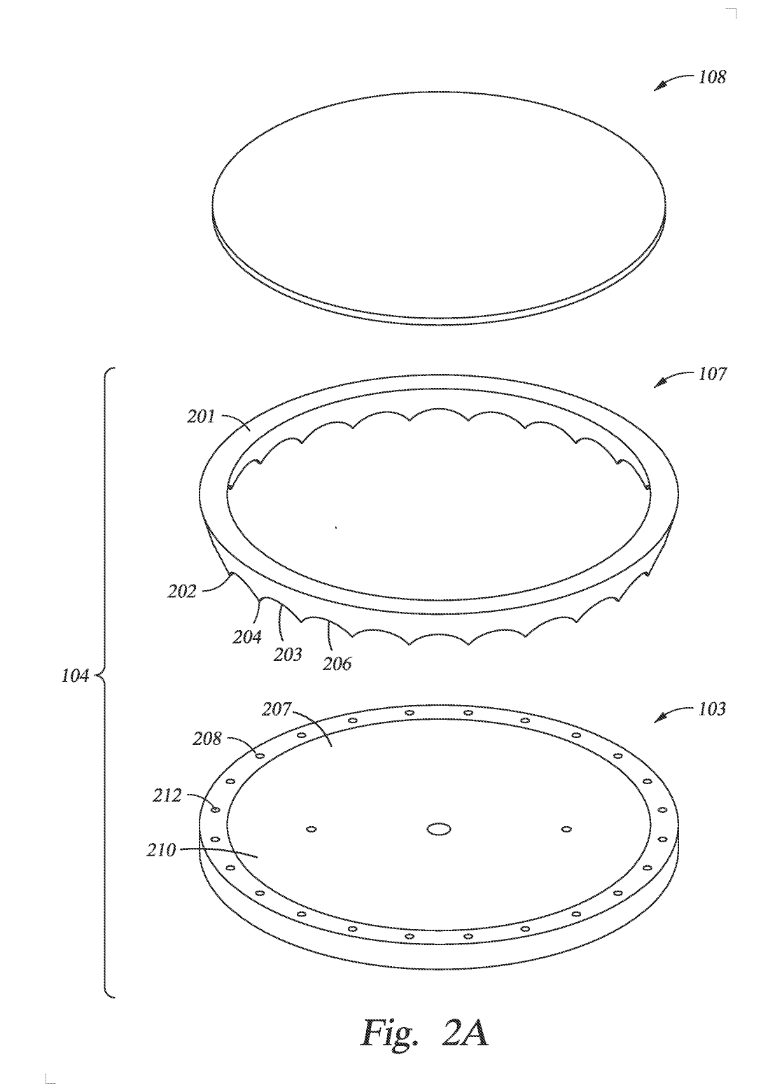

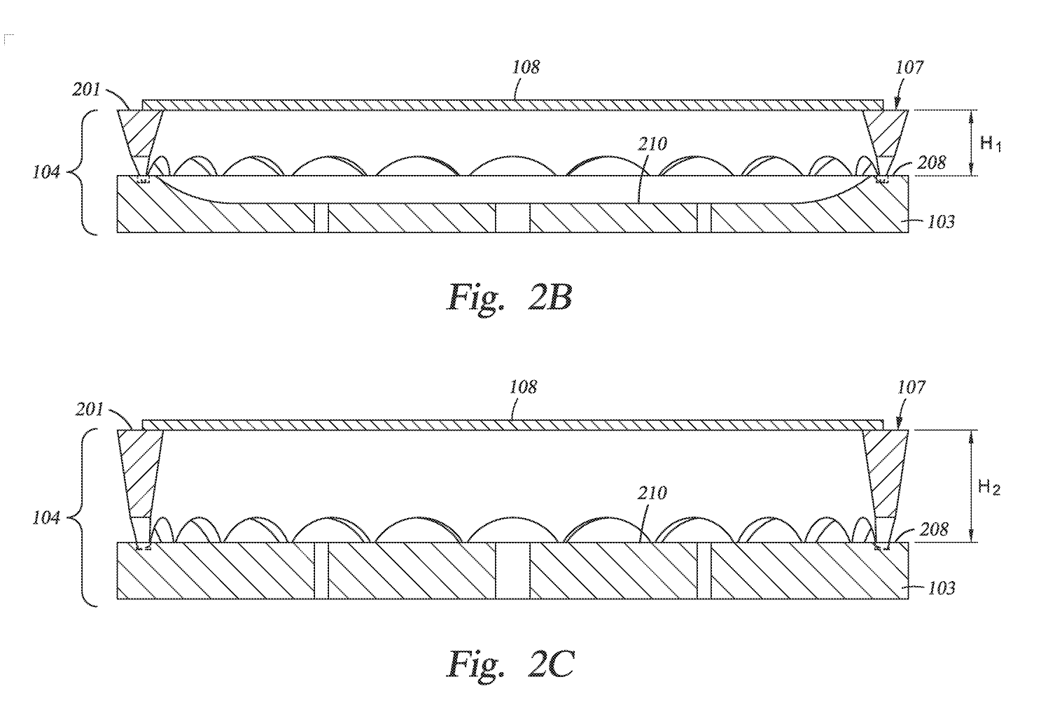

FIGS. 2A-2C illustrate a substrate support assembly according to embodiments described herein. FIG. 2A is an exploded view of the substrate support assembly 104 according to embodiments described herein. The substrate support assembly 104 includes the substrate support ring 107 and the susceptor 103. The substrate support ring 107 includes a first surface 201 and a second surface 203 opposite the first surface 201. The substrate 108 is disposed on the first surface 201 of the substrate support ring 107 during operation, and more particularly, the edge of the substrate 108 is in contact with the substrate support ring 107. The second surface 203 includes at least three protrusions 202 and each protrusion 202 has a tip 204. The tip 204 may be disposed on the susceptor 103. The susceptor 103 may be made of silicon carbide or graphite coated silicon carbide, so the susceptor 103 may absorb radiant energy from the lamps 102 disposed below and heat the substrate 108. The tip 204 may be pointed so the contact area between the substrate support ring 107 and the susceptor 103 may be very small. In addition, the substrate support ring 107 may be made of a material that has poor thermal conductivity, such as quartz. Thus, the unwanted edge heating of the substrate 108 is minimized due to the small contact area between the substrate support ring 107 and the heated susceptor 103.

A curved surface 206, such as an arc, may be formed between adjacent tips 204. The curved surface 206 does not have any stress concentrating areas since the curved surface 206 does not contain any sharp angles. Such design helps maintain the structure integrity of the substrate support ring 107 at elevated temperatures. Thus, the maximum number protrusions 202 may depend on the degree of curvature of the curved surfaces 206. Too many protrusions 202 may result in sharp angled surfaces between protrusions. In one embodiment, there are at least three protrusions. Because the edge of the substrate 108 makes continuous contact with the first surface 201 of the substrate support ring 107, which prevents process gases from flowing across the back side of the substrate 108, backside deposition on the substrate 108 is minimized.

The susceptor 103 includes a top surface 207 facing the substrate support ring 107. The top surface 207 may include an outer portion 208 and an inner portion 210. The substrate support ring 107 may be disposed on the outer portion 208. At least three recesses 212, such as holes or grooves, may be formed in the outer portion 208 to control the position of the substrate support ring 107 relative to the susceptor 103. As the substrate support ring 107 is placed on the susceptor 103, each tip 204 may be placed in a corresponding recess 212 disposed in the outer portion 208 of the susceptor 103. As the susceptor 103 is rotated by the shaft 132 (shown in FIG. 1) during operation, the substrate support ring 107 may be stationary with respect to the susceptor 103. The inner portion 210 may be a curved surface, as shown in FIGS. 2A and 2B, or may be a substantially flat surface, as shown in FIG. 2C.

FIG. 2B is a cross sectional side view of the substrate support assembly 104 supporting the substrate 108 according to one embodiment described herein. As shown in FIG. 2B, the susceptor 103 has a curved inner portion 210. As the substrate 108 bows towards the inner portion 210, the curved inner portion 210 ensures that substrate 108 is not touching the heated susceptor 103. In this configuration, the height “H1” of the substrate support ring 107 may be relatively small, such as between about 3 mm and about 10 mm.

FIG. 2C is a cross sectional side view of the substrate support assembly 104 supporting the substrate 108 according to another embodiment described herein. As shown in FIG. 2C, the susceptor 103 has a flat inner portion 210. Thus, the height “H2” of the substrate support ring 107 may be greater than the height “H1”, and the height “H2” may be between about 4 mm and about 10 mm, in order to prevent the bowed substrate 108 from contacting the heated susceptor 103.

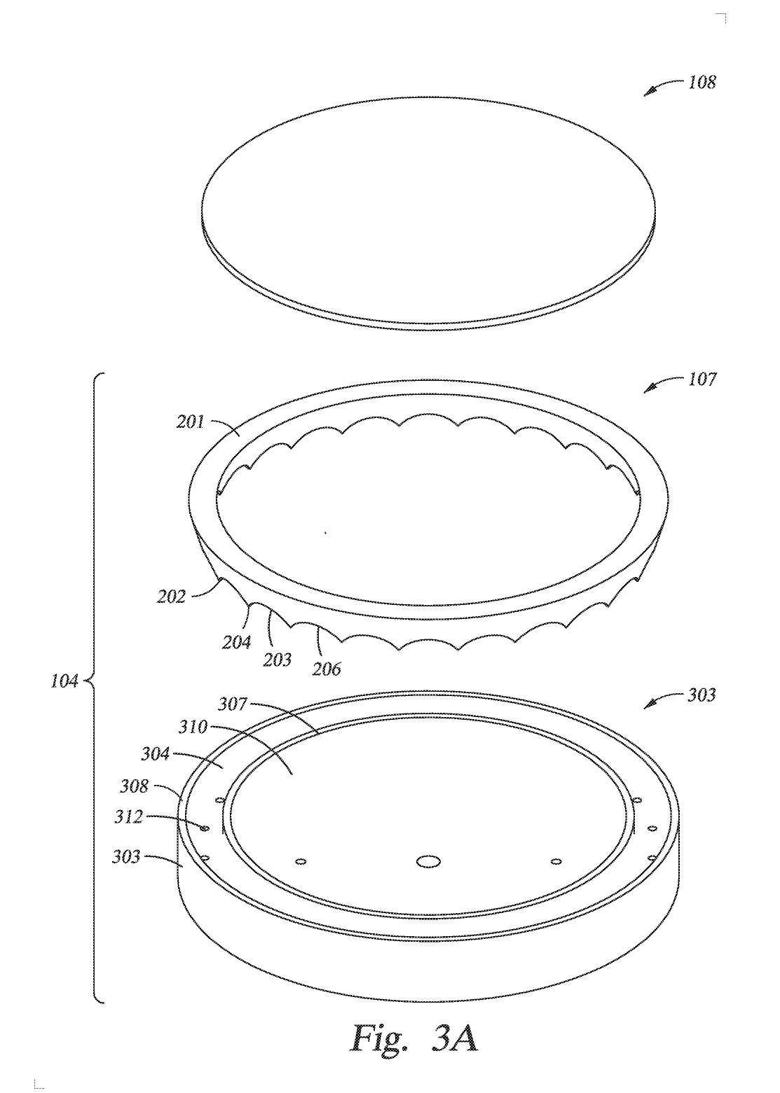

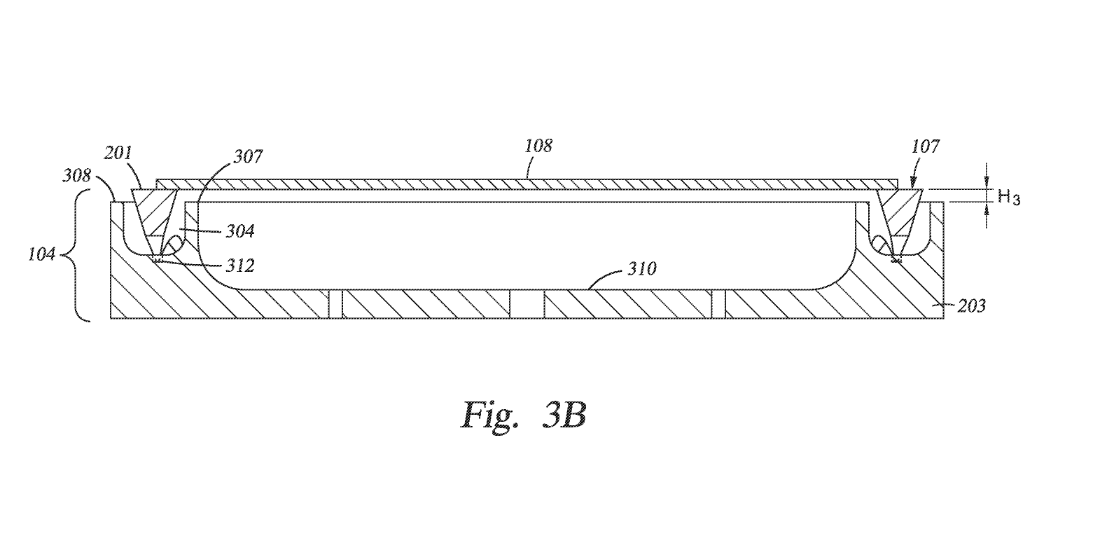

FIGS. 3A-3B illustrate the substrate support assembly 104 according to embodiments described herein. FIG. 3A is an exploded view of the substrate support assembly 104 according to embodiments described herein. The substrate support assembly 104 includes the substrate support ring 107 and a susceptor 303. The susceptor 303 includes a top surface 307 facing the substrate support ring 107. The top surface 307 may include an outer portion 308 and an inner portion 310. A groove 304 may be formed in the outer portion 308 and at least three recesses 312 are formed in the groove 304 to control the position of the substrate support ring 107 relative to the susceptor 303. As the substrate support ring 107 is placed in the groove 304, each tip 204 may be placed in a corresponding recess 312 disposed in the groove 304. The width of the groove may be wider than the first surface 201 of the substrate support ring 107, so a portion of the substrate support ring 107 may be below the top surface 307 of the susceptor 303.

FIG. 3B is a cross sectional view of the substrate support ring 107 and the susceptor 303 according to one embodiment described herein. As shown in FIG. 3B, the substrate support ring 107 is disposed in the groove 304 formed in the outer portion 308 of the susceptor 303. In this configuration, the second surface 203 (shown in FIG. 3A) is disposed inside the groove 304 and below the outer portion 308. Thus, the curved 206 surface, such as a plurality of arcs, is disposed in the groove 304 and below the outer portion 308. As a result of having the arcs disposed below the outer portion 308, the laminar flow of the process gases across the upper surface 116 of the substrate 108 (shown in FIG. 1) is not disturbed. The distance “H3” between the first surface 201 and the outer portion 308 may be between about 0.1 mm and about 0.5 mm.

The substrate support assemblies described herein include a susceptor and a substrate support ring disposed on the susceptor. The substrate support ring may have at least three protrusions and each protrusion has a tip. The tips of the substrate support ring may be in contact with the susceptor, and the small contact area between the substrate support ring and the susceptor minimizes the unwanted heating of the edge of a substrate that is disposed on the substrate support ring.

While the foregoing is directed to embodiments of the disclosure, other and further embodiments may be devised without departing from the basic scope thereof, and the scope thereof is determined by the claims that follow.

1. An apparatus, comprising:
a susceptor; and
a substrate support ring disposed on a surface of the susceptor, wherein the substrate support ring has a first surface for receiving a substrate and a second surface opposite the first surface, wherein the second surface has at least three protrusions, each protrusion has a tip, and each tip is in contact with the susceptor.

2. The apparatus of claim 1, wherein the surface of the susceptor has an inner portion and an outer portion, and the substrate support ring is disposed on the outer portion of the surface of the susceptor.

3. The apparatus of claim 2, further comprising at least three recesses formed in the outer portion of the surface of the susceptor, wherein each tip of the substrate support ring is placed in a corresponding recess.

4. The apparatus of claim 3, further comprising a groove disposed in the outer portion of the surface of the susceptor, wherein the at least three recesses are formed in the groove.

5. The apparatus of claim 1, where in the substrate support ring further includes a curved surface between adjacent tips.

6. The apparatus of claim 5, wherein the curved surface is an arc.

7. The apparatus of claim 2, wherein the inner portion is flat, and the substrate support ring has a height between about 4 mm and about 10 mm.

8. The apparatus of claim 2, wherein the inner portion is curved, and the substrate support ring has a height between about 3 mm and about 10 mm.

9. An apparatus, comprising:
a chamber body; and
a substrate support assembly disposed in the chamber body, wherein the substrate support assembly comprises:
a susceptor; and
a substrate support ring disposed on a surface of the susceptor, wherein the substrate support ring has a first surface for receiving a substrate and a second surface opposite the first surface, wherein the second surface has at least three protrusions, each protrusion has a tip, and each tip is in contact with the susceptor.

10. The apparatus of claim 9, wherein the surface of the susceptor has an inner portion and an outer portion, and the substrate support ring is disposed on the outer portion of the surface of the susceptor.

11. The apparatus of claim 10, further comprising at least three recesses formed in the outer portion of the surface of the susceptor, wherein each tip of the substrate support ring is placed in a corresponding recess.

12. The apparatus of claim 11, further comprising a groove disposed in the outer portion of the surface of the susceptor, wherein the at least three recesses are formed in the groove.

13. The apparatus of claim 9, where in the substrate support ring further includes a curved surface between adjacent tips.

14. The apparatus of claim 13, wherein the curved surface is an arc.

15. The apparatus of claim 10, wherein the inner portion is flat, and the substrate support ring has a height between about 4 mm and about 10 mm.

16. The apparatus of claim 10, wherein the inner portion is curved, and the substrate support ring has a height between about 3 mm and about 10 mm.

17. The apparatus of claim 9, wherein the substrate support ring comprises quartz.

18. An apparatus, comprising:
a susceptor having a surface, wherein at least three recesses are formed in the surface of the susceptor; and
a substrate support ring disposed on the surface of the susceptor, wherein the substrate support ring has a first surface for receiving a substrate and a second surface opposite the first surface, wherein the second surface has at least three protrusions, each protrusion has a tip, and each tip is placed in a corresponding recess of the at least three recesses.

19. The apparatus of claim 18, further comprising a groove disposed in the surface of the susceptor, wherein the at least three recesses are formed in the groove.

20. The apparatus of claim 18, where in the substrate support ring further includes a curved surface between adjacent tips.
